(19) United States
(12) Patent Application Publication
(10) Pub. No.: US 2023/0185985 A1
(43) Pub. Date: Jun. 15, 2023

(54) METHOD FOR FITTING PARTS TO STEEL PROFILES AS WELL A SYSTEM FOR PERFORMING THE METHOD

(71) Applicant: Voortman Steel Machinery Holding B.V., Rijssen (NL)

(72) Inventor: Arend VOORTMAN, Rijssen (NL)

(73) Assignee: Voortman Steel Machinery Holding B.V., Rijssen (NL)

(21) Appl. No.: 17/924,509

(22) PCT Filed: Jun. 4, 2021
(86) PCT No.: PCT/NL2021/050356

§ 371 Date: Nov. 10, 2022

(30) Foreign Application Priority Data
Jun. 4, 2020 (NL) 2025761

(51) Int. Cl. G06F 30/17

(52) U.S. Cl. CPC G06F 30/17

(57) ABSTRACT

Method and assembly for assisting a fitter in fitting parts to profiles for manufacturing construction elements of a steel construction. With the method, by using a software application fitting information is generated on the basis of the information obtained from 3D-model data of a 3D-model of the steel construction. The software application interprets 3D-model data and generates for at least one mark or phase of the steel construction a digital or physical list of parts which provides the logistical order in which the parts are supplied to the fitter and a digital or physical list of profiles which provides the logistical order in which profiles are supplied to the fitter. Additionally, specific welding parameter information for each part which has to be welded to a respective profile and graphical information which is presented on a screen which is in the working environment of the fitter may be generated.

### FIELD

The invention relates to fitting parts to steel profiles as well as to a computer system for performing the method.

### BACKGROUND

A steel profile may later get the function of e.g. a column, a beam, e.g. a floor beam, and a reinforcement beam, like a bracing, in a steel construction, like a building. In order to be able to connect the profiles so as to form the steel construction, parts have to be welded to the various profiles. The relevant parts consist of plates, or other profiles, e.g. tubes having square, rectangular or circular cross sections, flat bars, angle lines U- or I-profiles, or bolts. In the relevant field, connecting steel parts to profiles is referred to as fitting. The end product of fitting is a set of profiles with parts welded on the respective profiles. In a subsequent step, the set or a part of the set of profiles with parts welded thereon is transported to the building site and assembled to create the desired steel construction. A set of profiles with parts welded thereon may relate to what is called a “mark” which is a sub-assembly of the steel construction comprising at least one or a number of profiles fitted with parts. In the field, also the term “phase” is used to refer to a sub-assembly of the steel construction comprising a number of profiles fitted with parts. A phase may include several marks.

The fitter is supplied with a set of profiles which have been pre-manufactured and which have the right length, the right profile ends configuration and possibly holes and markings. The markings may be helpful to position parts on the profiles during the welding of the parts on the profiles. The parts which have to be welded to the profiles are supplied to the fitter and have been pre-manufactured to have the right dimensions and configuration, for example, holes, angles etc. In a first step, the parts are correctly positioned relative to the profile and by means of a tack-weld connected. In a subsequent step, a final weld is applied to definitely connect the respective part to the profile.

Up to now, a planning engineer will interpret the 3D CAD-model and prepare a set of drawings for each profile and the associated set of parts to be connected to that profile. These drawings are provided to the fitter and the fitter has to interpret the drawings and on the basis of the drawing information select the right part for the respective profile from a collection of parts which have been supplied to the fitter.

Subsequently, the fitter has to extract from the drawing information which relates to the orientation of the part relative to the profile so as to be able to position the part correctly relative to the profile. Optionally, markings or holes which may have been provided on and in the profile in the pre-manufacturing step may serve as reference points and may be helpful for positioning the part relative to the profile. After the positioning, a tack-welding step has to be performed by the fitter so as to provisionally connect the part to the profile at the right position on the profile and optionally with a desired gap between the part and the profile. After connecting one or more parts to a profile by tack-welding, in a subsequent step final welds may be applied to securely connect the respective parts to the profile.

All these steps are performed by hand and require a lot of knowledge and accuracy from the fitter. Selection of the right part may be time consuming and even the wrong part may be selected because some parts of the supplied set of parts may look very similar. Determining the orientation of the part relative to the profile and positioning the part relative to the profile may also go wrong. Also, during the final welding, wrong choices may be made with respect to the welding parameters.

US 2013/0282160 A1 discloses a computer controllable steel fabrication machine. The machine may be operated to cut a work piece to length, cut holes on any face of the work piece, apply an identification mark to the work piece, weld a cleat, and spray paint the finished item. A method for operating the machine includes an extraction and processing step, wherein a 3D Structure Model is converted into a database containing a sequence of primary and secondary members, their interrelationships and the tasks that must be carried out in order to transform the primary and secondary members into the articles originally specified in the 3D Structure Model. US2013/0282160 A1 does not include information relating to a method for assisting a fitter in performing his tasks. Instead, it discloses a system for automatically producing fitted profiles with a computer controllable steel fabrication machine.

### SUMMARY

The present invention has as an object to provide a method which assists the fitter with performing his tasks and with which the above described difficulties of his job are alleviated.

To that end, the invention provides the method according to claim 1. In particular, the invention provides a method for assisting a fitter in fitting parts to profiles for manufacturing construction elements of a steel construction. The parts consist of plates, profiles or bolts. Profiles may for example include tubes having square, rectangular or circular cross sections, flat bars, angle lines, and U- or I-profiles. The method comprises:
providing a computer system in which a 3D-model of the steel construction is created by means of a CAD-program;
providing a software application for generating fitting information, wherein the software application interprets 3D-model data of the 3D-model and generates for at least one mark or phase of the steel construction from the 3D-model data at least:
   a digital or physical list of parts which provides the logistical order in which the parts are supplied to the fitter;
   a digital or physical list of profiles which provides the logistical order in which profiles are supplied to the fitter;
   specific welding parameter information for each part which has to be welded to a respective profile, e.g. type of weld, welding voltage/amperage, weaving pattern; and
   graphical information which is presented on a screen which is in the working environment of the fitter, wherein the graphical information includes at least one of:
      various views of a profile in combination with a part to be connected with the profile;
      information on how to position a part relative to a profile; and
      information with respect to distances of the part relative to reference points, which reference points include at least one of an end face of the profile, holes in the profile or markings on the profile, so as to determine the precise position of the respective part on the respective profile relative to the reference points;
wherein the fitting information is provided to the fitter and wherein the fitter performs the following method steps for the at least one mark or phase of the steel construction for which the profiles have to be fitted by the fitter:
a) obtain the digital or physical list of profiles generated by the software application for the respective mark or phase and determine whether a next upcoming profile is available for processing, and
   a1) if available, taking that next upcoming profile from that list (22) for processing by the fitter and proceed at b); and
   a2) if not available, end the method;
b) obtain the digital or physical list of parts generated by the software application for the respective mark or phase and present a next upcoming part from that list to the fitter;
c) orient and position the part in the correct orientation and position relative to the reference points of the profile using the graphical information which is presented on the screen which is in the working environment of the fitter; and
d) tack-weld the respective part to the respective profile;
e) determine whether all parts for the respective profile have been connected to the profile and restart at step b) if the determination is “no” and restart at step a) if the determination is “yes”.

The invention also provides an assembly according to claim 12. In particular the invention provides an assembly comprising:
a computer system in which a 3D-model of the steel construction is created by means of a CAD-program;
a screen, like a computer screen or a tablet which is in the working environment of the fitter who has to perform the method according to anyone of claims 1-4;
a software application for generating fitting information, wherein the software application is configured to interpret the 3D-model data of the 3D-model and to generate for at least one mark or phase of the steel construction from the 3D-model data at least the following fitting information:
   a digital or physical list of parts which provides the logistical order in which the parts are supplied to a fitter;
   a digital or physical list of profiles which provides the logistical order in which profiles are supplied to the fitter;
   specific welding parameter information for each part which has to be welded to a respective profile, e.g. type of weld, welding voltage/amperage, weaving pattern; and
   graphical information which is presented on the screen which is in the working environment of the fitter, wherein the graphical information includes at least one of:
      various views of a profile in combination with a part to be connected with the profile;
      information on how to position a part relative to a profile; and
      information with respect to distances of the part relative to reference points, which reference points include at least one of an end face of the profile, holes in the profile or markings on the profile, so as to determine the precise position of the respective part on the respective profile relative to the reference points.

With the method and the assembly according to the invention, the difficulties of the job of the fitter are alleviated. The chance of making mistakes is reduced. Also, the time for fitting the profiles of a mark or phase of a steel construction is reduced by the fact that all selection of the profiles and parts requires less or even no time because the profiles and parts may be presented or supplied in the right order to the fitter. Also, the required information with respect to orientation and positioning of a respective part relative to a respective profile is presented at a screen in the working environment of the fitter. In fact, critical dimensions, distances of the part relative to reference points may be shown to the fitter on a screen.

In an embodiment, step d) of the method may include:

d1) prepare final welds for the part which has been tack-welded onto the respective profile in accordance with the specific welding parameter information (24) which is determined by the software application (18).

In this embodiment, after connecting a part, e.g. a plate, to the profile by tack-welding, the final welds are immediately applied.

In another embodiment, step e) may include before a restart is made at step a):

e1) prepare final welds for all the parts which have been tack-welded onto the respective profile in accordance with the specific welding parameter information (24) which is determined by the software application (18).

In this embodiment, after connecting all parts to the profile by tack-welding, the final welds are all applied for all the parts which have been connected to that profile.

In yet another embodiment, step a2) includes before ending the method:

a3) prepare final welds for all the parts which have been tack-welded onto the respective profiles of the mark or phase in accordance with the specific welding parameter information (24) which is determined by the software application (18).

In this embodiment, first all the profiles of a mark or phase are tack-welded onto the respective profiles of the mark or phase. Subsequently, the final welding is applied to all parts on all profiles of the respective mark or profile.

The welding parameters and the type of weld which has to be applied is presented for each connection to be made. No extensive special knowledge is required by the fitter which makes the job of the fitter easier and which makes it even possible to perform the job of fitting with less experienced work force.

In an embodiment, the method may comprise:
pre-collecting the parts and placing the parts in a stack having an order which is in accordance with the digital or physical list of parts generated by the software application,
performing step b) by taking a subsequent or upper part from the stack.

An embodiment of the assembly for performing this embodiment of the method may comprise a part collector device in which parts are collected and placed in a supply order which is in accordance with the digital or physical list of parts generated by the software application. For plates, the supply order may be formed by a stack of plates which have to be subsequently connected to the profiles.

With this embodiment of the method and the system, the selection of the right part is very easy for the fitter because the parts have been pre-collected and are supplied in the right supply order. The formation of a supply order of parts, e.g. the formation of a stack of plates, may have been done by a person but, as is clear from the embodiment of the assembly, may also be performed automatically. To that end, the part collector device may collect the correct parts and place the parts in the right supply order, e.g. in the right order in a stack when the parts are plates. That stack can then be supplied to the fitter who simply has to take each time a subsequent or upper part from the stack when performing his task. The collecting can be effected by selection from a stock or by manufacturing the parts in the desired order in accordance with the generated list and by supplying the parts in this order to the part collector device. The chance of making mistakes during the fitting is reduced by automatically presenting the right part to the fitter as the subsequent part from the supply order of parts, e.g. the upper part from the pre-collected stack of plates.

In an embodiment, the method may comprise:
pre-collecting the profiles on a transport system in a supply order which is in accordance with the digital or physical list of profiles generated by the software application,
performing step a) by subsequently transporting the profiles to the fitter with the transport system.

An embodiment of the assembly for performing this embodiment of the method may comprise a transport system which is configured to subsequently supply profiles to the fitter in an order which is in accordance with the digital or physical list of profiles generated by the software application.

With this embodiment, the fitter is automatically presented with the correct profile when performing his job. As with the parts, the pre-collecting may be performed by selecting the correct profiles from a stock or by manufacturing the profiles in the desired order in accordance with the generated list and supplying the profiles in this order to the transport system. The chance of making mistakes during the fitting is reduced by automatically presenting the right profile to the fitter.

In an embodiment of the method, the fitting information also includes information relating to the dimensions of the parts relative to the reference points, and wherein the fitter, after executing step b) and before executing step c) checks whether the part to be tack-welded to the profile indeed fulfills the dimensional requirements relative to the reference points.. The reference points may determine the positional relation between the respective part and the respective profile. The use of markings on the profiles, which markings have been applied during the pre-manufacturing of the profiles, may be very helpful to reduce the risk of mistakes. Additionally, by virtue of the present embodiment, the actual dimensions of a part, e.g. the actual outer dimensions, may be checked by the fitter relative to the reference points so as to determine whether any deviations of the actual dimensions from the theoretically prescribed dimensions may lead to interference with other construction elements of the steel construction when the construction elements are assembled. It is known that during the pre-manufacturing of parts and profiles, i.e. before the fitting is done, some deviations of the dimensions may occur. However, many of these deviations are not influencing the integrity of the assembled steel construction but some deviations may lead to problems during assembly, for example, problems which prevent assembling of the various construction elements. This may, for example, be caused by a part which is fitted to the profile and which is in one direction a little too large and thus extends beyond and end face of the profile thereby making it impossible to connect the construction element with that end face to another construction element. By virtue of the present embodiment, the fitter is provided with the relevant dimensional information so that he/she will be able to determine whether a dimensional deviation is prohibitive to use the part or not.

In an embodiment, the fitting information which is generated by the software application (18) may include:
a digital or physical schedule showing the work order in which the various profiles and parts have to be processed. and
If such a digital or physical schedule is available, the method may include:
processing the various profiles and parts in accordance with the work order shown on the digital or physical schedule.

Of course, the digital or physical list (20) of parts and the digital or physical list of profiles will in this embodiment correspond with the work order which is presented on the digital or physical schedule. The schedule may be helpful for the fitter to obtain a good overview of the work which still has to be done and the work which has been finished.

In a further elaboration of this embodiment, the fitting information which is generated by the software application (18) may include:
status information which allows for live monitoring of the status of the fitting process of the respective mark or phase.

Such status information which allows for live monitoring of the status of the fitting process may not only provide insight to the fitter in the status of his work but also to a supervisor or a planner who has to plan other jobs to be performed by the fitter or other jobs at which the phases or marks which have been fitted with the present method are required. Such live status information may be available at a position remote from the place where the fitter performs his task, e.g. in an office space where the planner of a project does his job.

In an embodiment, the method may include automatically uploading the specific welding parameter information (24) for each part which has to be welded to a respective profile into the welding apparatus.

For applying this embodiment method, the assembly will be provided with a welding apparatus. By virtue of this embodiment, the time needed for inputting the right welding parameters into the welding apparatus is reduced dramatically. Additionally, the chance of making mistakes when inputting welding parameters into the welding apparatus is dramatically reduced relative to manually inputting such data.

In an embodiment, the automatically uploading of welding information for a specific weld may be triggered by a fitter who taps on the screen at a position where that weld is shown on the screen.

Thus, the welding apparatus is provided with the correct welding data at the moment that the fitter is ready for making the next weld.

### BRIEF DESCRIPTION OF THE FIGURES

FIG. 1 shows a schematic representation of an example of the assembly according to the invention; and

FIGS. 2A and 2B show a flow diagram of the method according to the invention.

### DETAILED DESCRIPTION

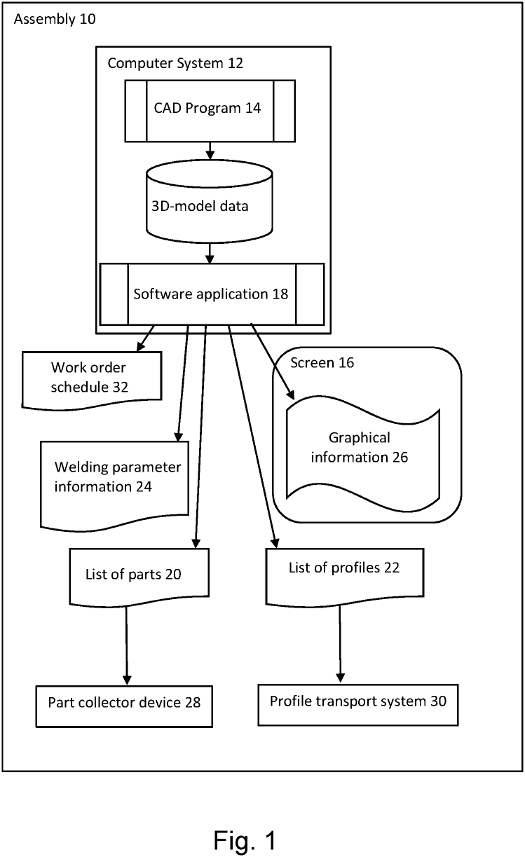

FIG. 1 shows a schematic representation of an example of the assembly according to the invention. For a detailed description of the assembly reference is made to the summary. The various reference numbers in the figure refer to the following:

| | |
|---|---|
| 10 | assembly |
| 12 | computer system |
| 14 | CAD-program |
| 16 | screen |
| 18 | software application |
| 20 | digital or physical list of parts |
| 22 | digital or physical list of profiles |
| 24 | specific welding parameter information |
| 26 | graphical information; |
| 28 | part collector device |
| 30 | profile transport system |
| 32 | schedule of work order |

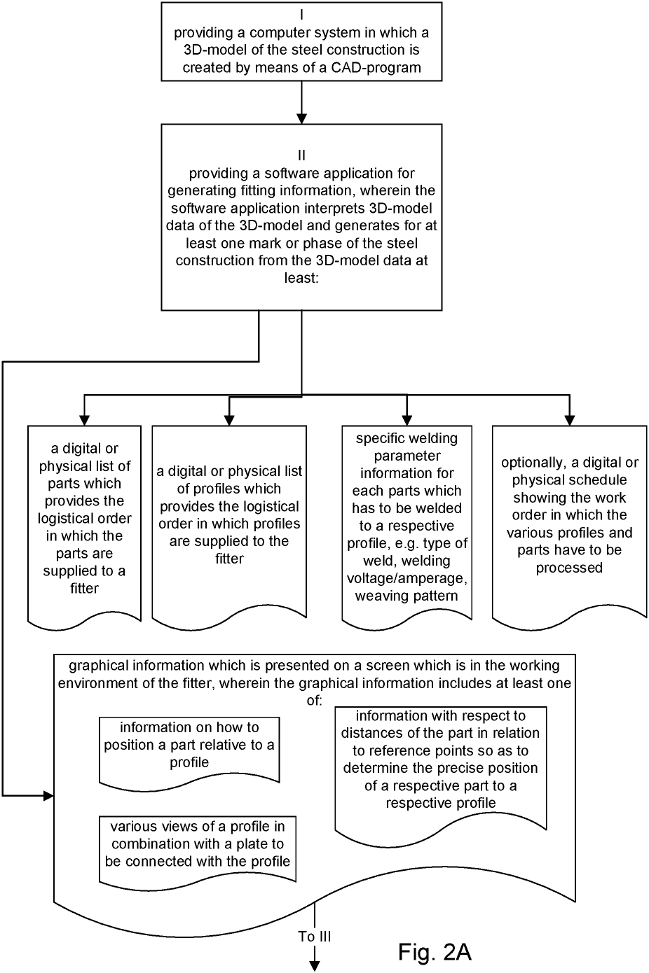

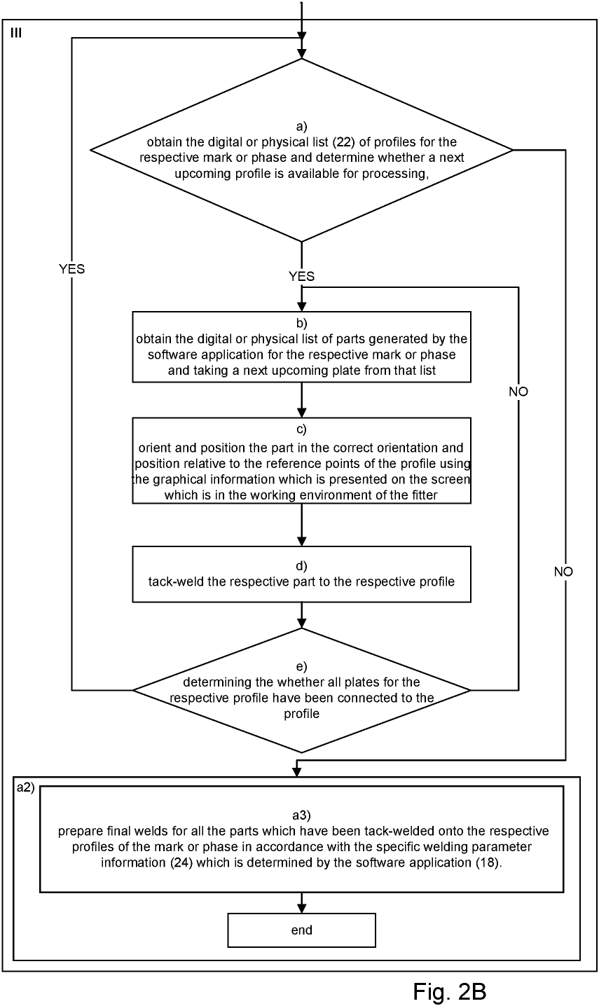

FIGS. 2A and 2B show a flow diagram of an embodiment of the method according to the invention. In this figure each method step is represented by a block. The figure merely elucidates the various steps and for a detailed description of the method reference is made to the summary. In fact, the embodiment shown in FIGS. 2A and 2B is in accordance with the embodiment claimed in claim 4.

The various embodiments which are described above may be implemented independently from one another and may be combined with one another in various ways. The reference numbers used in the detailed description and the claims do not limit the description of the embodiments nor do they limit the claims. The reference numbers are solely used to clarify by referring to the non-limiting example in the figures.

1. A method for assisting a fitter in fitting parts to profiles for manufacturing construction elements of a steel construction, the parts consisting of plates, profiles or bolts, wherein the method comprises:
providing a computer system in which a 3D-model of the steel construction is created by means of a CAD-program;
providing a software application for generating fitting information, wherein the software application interprets 3D-model data of the 3D-model and generates for at least one mark or phase of the steel construction from the 3D-model data at least the following fitting information:
a digital or physical list of parts which provides the logistical order in which the parts are supplied to the fitter;
a digital or physical list of profiles which provides the logistical order in which profiles are supplied to the fitter;
specific welding parameter information for each part which has to be welded to a respective profile; and
graphical information which is presented on a screen which is in the working environment of the fitter,
wherein the graphical information includes at least one of:
various views of a profile in combination with a part to be connected with the profile;
information on how to position a part relative to a profile; and
information with respect to distances of the part relative to reference points, the reference points including at least one of an end face of the profile, holes in the profile or markings on the profile, so as to determine a precise position of the respective part on the respective profile relative to the reference points,
wherein the fitting information is provided to the fitter and wherein the fitter performs the following method steps for the at least one mark or phase of the steel construction for which the profiles have to be fitted by the fitter:
a) obtain the digital or physical list of profiles generated by the software application for the respective mark or phase and determine whether a next upcoming profile is available for processing, and
a1) if available, taking a next upcoming profile from the list for processing by the fitter and proceed at step b); and
a2) if not available, end the method;
b) obtain the digital or physical list of parts generated by the software application for the respective mark or phase and present a next upcoming part from the list to the fitter;
c) orient and position the part in the correct orientation and position relative to the reference points of the profile using the graphical information which is presented on the screen which is in the working environment of the fitter;
d) tack-weld the respective part to the respective profile; and
e) determine whether all parts for the respective profile have been connected to the profile and restart at step b) if the determination is “no” and restart at step a) if the determination is “yes”.

2. The method according to claim 1, wherein step d) includes:
d1) prepare final welds for the part which has been tack-welded onto the respective profile in accordance with the specific welding parameter information determined by the software application.

3. The method according to claim 1, wherein step e) includes before a restart is made at step a):
e1) prepare final welds for all the parts which have been tack-welded onto the respective profile in accordance with the specific welding parameter information determined by the software application.

4. The method according to claim 1, wherein step a2) includes before ending the method:
a3) prepare final welds for all the parts which have been tack-welded onto the respective profiles of the mark or phase in accordance with the specific welding parameter information determined by the software application.

5. The method according to claim 1, comprising:
pre-collecting the parts and placing the parts in a supply order in accordance with the digital or physical list of parts generated by the software application; and
performing step b) by taking a subsequent or upper part from the supply order.

6. The method according to claim 1, comprising:
pre-collecting the profiles on a transport system in a supply order in accordance with the digital or physical list of profiles generated by the software application; and
performing step a) by subsequently transporting the profiles to the fitter with the transport system.

7. The method according to claim 1, wherein the fitting information also includes information relating to the dimensions of the parts relative to the reference points, and wherein the fitter, after executing step b) and before executing step c) checks whether the part to be tack-welded to the profile indeed fulfills the dimensional requirements relative to the reference points.

8. The method according to claim 1, wherein the fitting information which is generated by the software application includes:
a digital or physical schedule showing the work order in which the various profiles and parts have to be processed; and
wherein the method includes:
processing the various profiles and parts in accordance with the work order shown on the digital or physical schedule.

9. The method according to claim 8, wherein the fitting information which is generated by the software application includes:
status information which allows for live monitoring of the status of the fitting process of the respective mark or phase.

10. The method according to claim 1, wherein the method includes:
automatically uploading the specific welding parameter information for each part which has to be welded to a respective profile into the welding apparatus.

11. The method according to claim 10, wherein the automatically uploading of welding information for a specific weld is triggered by a user who taps on the screen at a position where that weld shown on the screen.

12. An assembly for use in the method according to claim 1, wherein the assembly comprises:
a computer system in which a 3D-model of the steel construction is created by means of a CAD-program;
a screen which is in the working environment of the fitter who has to perform the method; and
a software application for generating fitting information, wherein the software application is configured to interpret 3D-model data of the 3D-model and to generate for each mark or phase of the steel construction from the 3D-model data at least the following fitting information:
a digital or physical list of parts which provides the logistical order in which the parts are supplied to a fitter;
a digital or physical list of profiles which provides the logistical order in which profiles are supplied to the fitter;
specific welding parameter information for each part which has to be welded to a respective profile; and
graphical information presented on the screen in the working environment of the fitter,
wherein the graphical information includes at least one of:
various views of a profile in combination with a part to be connected with the profile;
information on how to position a part relative to a profile; and
information with respect to distances of the part relative to reference points, the reference points including at least one of an end face of the profile, holes in the profile or markings on the profile, so as to determine a precise position of the respective part on the respective profile relative to the reference points.

13. The assembly according to claim 12, wherein the assembly includes a part collector device in which parts are collected and placed on in a supply order in accordance with the digital or physical list of parts generated by the software application.

14. The assembly of claim 12, wherein the assembly includes a transport system configured to subsequently supply profiles to the fitter in a supply order in accordance with the digital or physical list of profiles generated by the software application.

15. The assembly of claim 12, wherein the software application is configured to generate fitting information which additionally includes:
a digital or physical schedule showing the work order in which the various profiles and parts have to be processed.

16. The assembly of claim 12, wherein the software application is configured to generate fitting information which additionally includes:
status information which allows for live monitoring of the status of the fitting process of the respective mark or phase.

17. The assembly of claim 12, wherein the assembly includes a welding apparatus and wherein the software application is configured to:
automatically upload the specific welding parameter information for each part which has to be welded to a respective profile into the welding apparatus.

18. The assembly according to claim 17, wherein the software application is configured to trigger the automatically uploading of the specific welding parameter information for a specific weld when a fitter taps on the screen at the position where that weld is shown on the screen.

19. The method according to claim 2, comprising:
pre-collecting the parts and placing the parts in a supply order in accordance with the digital or physical list of parts generated by the software application; and
performing step b) by taking a subsequent or upper part from the supply order.

20. The method according to claim 3, comprising:
pre-collecting the parts and placing the parts in a supply order in accordance with the digital or physical list of parts generated by the software application; and
performing step b) by taking a subsequent or upper part from the supply order.
